(19) United States
(12) Patent Application Publication
(10) Pub. No.: US 2011/0147568 A1
(43) Pub. Date: Jun. 23, 2011

(54) High density array module and connector

(75) Inventors: Michael Miyake, Placentia, CA (US); W. Eric Boyd, Irvine, CA (US)

(73) Assignee: Irvine Sensors Corporation, Costa Mesa, CA (US)

(21) Appl. No.: 12/928,797

(22) Filed: Dec. 16, 2010

Related U.S. Application Data
(60) Provisional application No. 61/284,393, filed on Dec. 18, 2009.

(51) Int. Cl. G01J 1/44; H05K 7/00

(52) U.S. Cl. 250/208.2; 361/728

(57) ABSTRACT

In a preferred embodiment of the invention, a high density interconnect structure is provided comprised of a dielectric structure and one or more compressible conductive member for the electrical connection of a plurality of inputs and outputs of a three-dimensional module to external circuitry using a compression frame and a flex connector. The compression frame has a surface equal to or less than the surface area of the module surface upon which it is mounted and permits a plurality of modules to be “butted” together to provide, for instance, a buttable focal plane array module comprising a mosaic of buttable focal plane arrays.

### CROSS-REFERENCE TO RELATED APPLICATIONS

This application claims the benefit of U.S. Provisional Patent Application No. 61/284,393, filed on Dec. 18, 2009 entitled, “High Density Array Connector”, pursuant to 35 USC 119, which application is incorporated fully herein by reference.

### STATEMENT REGARDING FEDERALLY SPONSORED RESEARCH AND DEVELOPMENT

N/A

### BACKGROUND OF THE INVENTION

1. Field of the Invention

The invention generally relates to the field of electrical connectors. More specifically, the invention relates to a high-density array module and electrical connector for use with a three-dimensional electronic module that permits a plurality of such modules to abut each other in an assembly, such as in a buttable focal plane array device.

2. Description of the Related Art

Applications such as mosaic focal plane array assemblies require a plurality of individual focal plane arrays (also know as “FPAs”) to be uniformly and precisely situated in the mosaic to minimize distortion and achieve high resolution in the image data outputs from the individual pixels in the mosaic. A preferred method of precise placement and alignment of the individual focal plane array elements in a mosaic of focal plane array elements is the use of precisely singulated photon detector arrays (e.g., a focal plane arrays or “FPAs”) and precisely singulated focal plane array support electronics in the form of integrated circuit die which are stacked and interconnected to define a three-dimensional, buttable module for use in a mosaic of “tiled” focal plane array modules.

What is lacking in the prior art and is needed is an electronic connector assembly for use with the above modules for the routing of input/output and power and ground signals to and from the individual electronic modules in a mosaic of modules. Additionally desirable is an electronic connector assembly that permits the selective and precise assembly and removal of an individual FPA module from the mosaic.

### BRIEF SUMMARY OF THE INVENTION

In a preferred embodiment of the invention, a high density interconnect structure is provided comprised of a dielectric interposer structure and one or more compressible conductive members for the electrical connection of a plurality of inputs and outputs in a three-dimensional module to external circuitry using a compression frame and a flexible connector. The compression frame has a surface equal to or less than the surface area of the module surface upon which it is mounted and permits a plurality of modules to be “butted” together to provide, for instance, a buttable focal plane array module.

In a first aspect of the invention, a buttable high density array electronic module and connector is disclosed comprising a stacked electronic module comprising an input/output surface area where the input/output surface area comprises an electrical input/output contact pad. A compression frame is bonded to the input/output surface area and comprises an interior volume and a compression frame area that is substantially equal to or less than the input/output surface area.

An electrical connector comprises at least one electrical routing contact pad for the routing of electrical signals to or from the module to external circuitry. An interposer is disposed within the interior volume comprising at least one aperture having a compressible conductive member disposed therein wherein the compressible conductive member is in electrical communication with at least one of the input/output contact pads and at least one of the routing contact pads.

In a second aspect of the invention, the compressible conductive member is a spring.

In a third aspect of the invention, the compressible conductive member is a helical spring.

In a fourth aspect of the invention, the compressible conductive member is a spring having a predetermined inductance.

In a fifth aspect of the invention, the compressible conductive member is a spring having a predetermined force constant.

In a sixth aspect of the invention, at least one compressible conductive member has a predetermined inductance characteristic and at least one other compressible conductive member has a predetermined force constant.

In a seventh aspect of the invention, the compressible conductive member is a fuzz button.

In an eighth aspect of the invention, the compression frame comprises at least one threaded aperture for receiving a threaded connector means such as a screw.

In a ninth aspect of the invention, the stacked electronic module comprises a photon detector array responsive to a predetermined range of the electromagnetic spectrum such as a micro-bolometer focal plane array.

In a tenth aspect of the invention, the electrical routing contact is in electrical connection with a discreet electronic component such as a capacitor.

While these and other aspects of the claimed apparatus and method herein have or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE SEVERAL VIEWS OF THE DRAWINGS

FIG. 1 depicts an exploded view of the high-density connector and module of the invention.

FIG. 2 is a cross-section of the compressible conductive member in the aperture of the interposer of FIG. 1.

FIG. 2A is a cross-section taken along 2A of FIG. 2.

FIG. 2B depicts a compressible conductive member in the form of a fuzz button.

FIG. 3 illustrates the assembled high density connector and module of FIG. 1.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

Turning now to the figures wherein like numerals define like elements among the several views, a preferred embodiment of the high density array and connector of the invention for use in, for instance, a buttable focal plane array module, is disclosed.

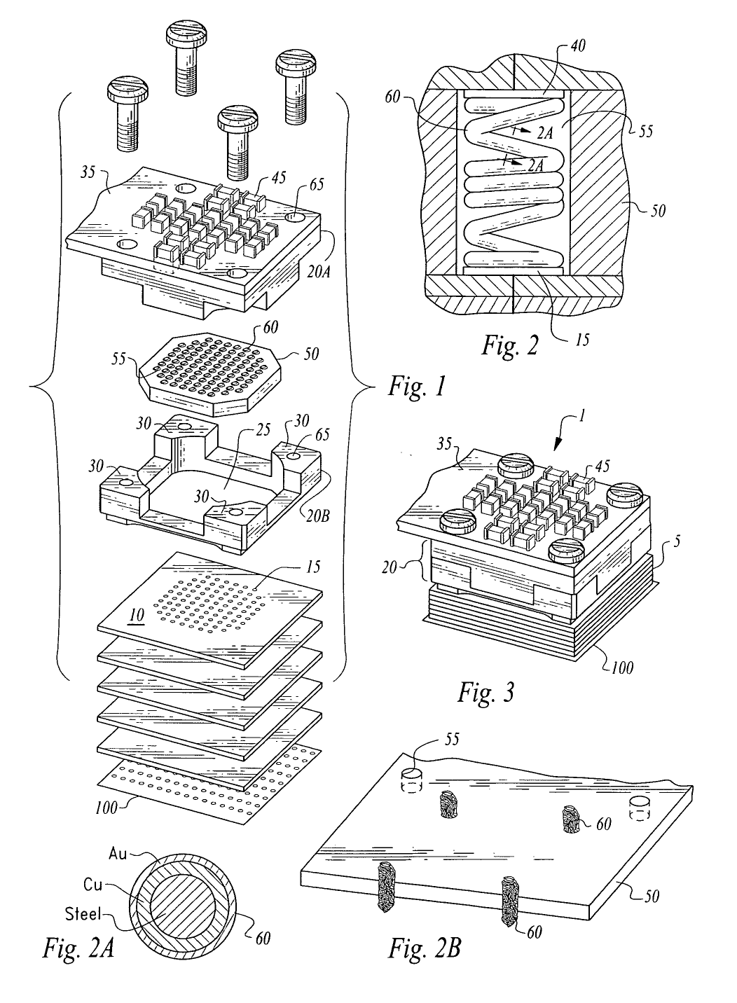

As seen in FIG. 1, FIG. 2, FIG. 2A, FIG. 2B and FIG. 3, the high density array and connector 1 comprise a stacked electronic module 5. Stacked module 5 comprises an input/output surface area 10. Input/output surface area 10 defines a plurality of electrical input/output contacts 15 such as conductive pads for the routing of electrical signals and power and ground from the stacked module 5.

Compression frame 20 is comprised of first and second compression frame elements 20A and 20B and is best shown in FIG. 1. Compression frame 20 is preferably fabricated from an aluminum, steel or copper material. Second compression frame member 20B is bonded to the input/output surface area 10 using an adhesive such as a suitable epoxy. Second compression frame member 20B defines an interior volume 25 and a compression frame area 30 that is substantially equal to or less than the input/output surface area 10.

An electrical connector 35 such as a rigid flex cable is provided comprising at least one electrical routing contact pad 40 for the routing of electrical signals to or from the module to external circuitry. Electrical connector 35 may optionally include discrete electronic components such as capacitors 45.

An interposer 50 is disposed within interior volume 25 comprising at least one aperture 55 having a compressible conductive member 60 disposed therein. Interposer 50 is preferably fabricated from a dielectric material such as FR-4 or Kapton or formed from a non-conductive plastic material such as ULTEM 1000 as is available from Gehr Plastics, Inc.

Compressible conductive member 60 is in electrical communication with at least one of the input/output contacts 15 and at least one of the routing contacts 40. Compressible conductive member 60 is preferably a “pogo pin” or a helical spring having a predefined force constant or predefined inductance or both, such as a SuperSpring available from Interposer Technologies, Inc. In the preferred embodiment, compressible conductive member has a low inductance at high frequencies and a low electrical resistance and is fabricated with a steel core coated with a high conductivity copper and an outer plating of gold.

In an alternative embodiment, the spring force constants and inductance characteristics of compressible conductive member 60 are individually predetermined for each input/output contact 15, depending on the mechanical and electrical characteristics of the individual input/output contact signal or structures.

A threaded aperture 65 is provided for receiving a threaded connector means such as a threaded screw or bolt element to permit the selective affixing or removal of electrical connector 35 to second compression frame element 20B.

In one embodiment of the invention, compressible conductive member 60 is a “fuzz button” manufactured from a single strand of 0.002″ gold-plated beryllium-copper wire compressed into a cylindrical shape as are available from Custom Interconnects, Inc.

An exemplar fuzz button disposed in interposer 50 is depicted in FIG. 2B.

The fuzz button embodiment of compressible conductive member 60 is not limited to a single wire strand construction and may be desirably fabricated from a plurality of wire strands or other electrically conductive materials with suitable mechanical and electrical properties for the end application of the conductor as is well-known in the materials arts.

A preferred embodiment of the fuzz button of 60 is a 0.020″ diameter cylindrical element. The single wire strand construction has the desirable attributes of relatively high temperature operation, reduced signal path and associated lower inductance and distortion. A random wire orientation in the structure of the fuzz button assists in the cancellation of electronic fields created by electrical conduction and has the further desirable attribute of compressibility of between 15% to 30% of its nominal original height.

This form of fuzz button conductor can be repeatedly (i.e., twenty or more times) compressed and decompressed while still retaining its nominal original height.

One or more fuzz button compressible conductive members 60 are disposed within and through the thickness of interposer 50 wherein the terminal ends of the fuzz button outwardly depend from the opposing first and second major planar surfaces of interposer 50.

A preferred method of fabricating interposer 50 is to drill through-holes in the requisite pattern through a dielectric layer for the retention of the body of compressible conductive member 60. In this manner, the respective terminal ends of compressible conductive member 60 are accessible from the respective sides of a dielectric layer of interposer 50 and provide an electrically conductive path through the thickness thereof. One or more registration holes may be provided through interposer 50 for the subsequent registration of with the conductive pads between which it will be disposed. Registration holes are used to maintain alignment of compressible conductive members 60 with the respective conductive pads upon which they will be disposed by using a registration pin mount when interposer 50 is mounted in the invention.

Stacked microelectronic modules are generally comprised of layers containing integrated electronic circuitry and are desirable in that three-dimensional structures provide increased circuit density per unit area. The elements in a three-dimensional module are typically arranged in a stacked configuration and may comprise stacked integrated circuit die, stacked prepackaged integrated circuit packages, stacked modified prepackaged integrated circuits or stacked neo-layers such as disclosed in the various U.S. patents below.

The patents below disclose devices and methods wherein layers containing integrated circuit chips are stacked and electrically interconnected using any number of stacking techniques. For example, Irvine Sensors Corporation, assignee of the instant application, has developed several patented techniques for stacking and interconnecting multiple integrated circuits. Some of these techniques are disclosed in U.S. Pat. Nos. 4,525,921; 4,551,629; 4,646,128; 4,706,166; 5,104,820; 5,347,428; 5,432,729; 5,688,721; 5,953,588; 6,117,704; 6,560,109; 6,706,971; 6,717,061; 6,734,370; 6,806,559 and U.S. Pub. No. 2006/0087883.

Generally speaking, in a three-dimensional module, components containing integrated circuits are bonded together one on top of another so as to maintain a “footprint” approximately equivalent to that of the largest layer in the stack. The input/output connections of the various integrated circuit die in the layers are electrically rerouted the lateral surface of the module or to conductive area interconnects or electrically conductive vias defined at one or more predetermined locations in the stack.

By way of example and not by limitation, stacked electronic module 5 may comprise layers of bare integrated circuit die (i.e., ASICs), commercial off-the-shelf (COTS) packaged parts, modified prepackaged parts or neo-layers.

Stacked electronic module 5 may be comprised of individual integrated circuit layers that are bonded together with a suitable adhesive to form an integral assembly. One of the layers may comprise a photon detector array responsive to a predetermined range of the electromagnetic spectrum such as a micro-bolometer focal plane array 100. One or more of the layers comprise integrated circuitry but may further comprise discrete embedded components such as resistors, inductors, capacitors and the like.

The layers of stacked electronic module 5 may comprise user-defined metalized conductive traces that are formed upon a planar surface of each layer as needed so as to reroute electronic signals, such as clock, enable, data, power, ground, etc. to the edge of the layer to form access lead. Access leads are selectively provided on one or a plurality of module peripheral surfaces. Additionally, conductive through-hole vias may be defined on the layers for the routing of electronic signals between the respective layers.

Conductive metal traces may be used to interconnect access leads between the layers in the module as well as rerouted to create one or more first contacts to electrically connect the module to one or more second contacts on an external surface such as an external printed circuit board.

When first and second compression frame members 20A and 20B are separated, module 5 may be mechanically separated from interposer 50, providing the benefit of the selective insertion or removal of a module from an external circuit without the need for reflowing solder ball connections, breaking wire bonds or conductive epoxy connections. Such a configuration is ideal for testing module performance and functionality in an external circuit without creating permanent metallurgical or adhesive circuit connections.

It is noted that any suitable compression frame geometry may be used to fixedly retain the module, interposer assembly and external circuitry or to apply the appropriate compressive force between first and second conductive pads to create a mechanical and electrical connection between the respective pads.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention.

What is claimed:

1. A high-density array electronic module and connector assembly comprising:
a stacked electronic module comprising an input/output surface area, the input/output surface area comprising an electrical input/output contact,
a compression frame bonded to the input/output surface area and comprising an interior volume and defining a compression frame area that is substantially equal to or less than the input/output surface area,
an electrical connector comprising at least one electrical routing contact for the routing of electrical signals to or from the module to external circuitry,
an interposer disposed within the interior volume comprising at least one aperture having a compressible conductive member disposed therein,
the compressible conductive member in electrical communication with at least one of the input/output contacts and at least one of the routing contacts.

2. The high-density array electronic module and connector assembly of claim 1 wherein the compressible conductive member is a spring.

3. The high-density array electronic module and connector assembly of claim 1 wherein the compressible conductive member is a helical spring.

4. The high-density array electronic module and connector assembly of claim 1 wherein the compressible conductive member is a spring having a predetermined force constant.

5. The high-density array electronic module and connector assembly of claim 1 wherein the compressible conductive member is a spring having a predetermined inductance.

6. The high-density array electronic module and connector assembly of claim 1 wherein at least one compressible conductive member has a predetermined inductance characteristic and at least one other compressible conductive member has a predetermined force constant.

7. The high-density array electronic module and connector assembly of claim 1 wherein the compressible conductive member is an electrically conductive fuzz button.

8. The high-density array electronic module and connector assembly of claim 1 wherein the compression frame comprises at least one threaded aperture for receiving threaded connector means.

9. The high-density array electronic module and connector assembly of claim 1 wherein the stacked electronic module comprises a photon detector array responsive to a predetermined range of the electromagnetic spectrum.

10. The high-density array electronic module and connector assembly of claim 1 wherein the electrical routing contact is in electrical connection with a capacitor.
